(19) United States
(12) Patent Application Publication
(10) Pub. No.: US 2026/0164984 A1
(43) Pub. Date: Jun. 11, 2026

(54) DISPLAY MODULE AND DISPLAY DEVICE

(71) Applicant: Wuhan Tianma Micro-Electronics Co., Ltd., Wuhan (CN)

(72) Inventor: Xin DAI, Wuhan (CN)

(21) Appl. No.: 19/314,902

(22) Filed: Aug. 29, 2025

(30) Foreign Application Priority Data
Dec. 9, 2024 (CN) 202411808318.2

(51) Int. Cl. H10K 59/80; H10K 59/131; H10K 102/00

(52) U.S. Cl. CPC H10K 59/80; H10K 59/131; H10K 2102/311

(57) ABSTRACT

A display module and a display device are provided. The display module includes a display panel, a support layer, a support structure, and an adhesive structure. The display panel includes a display portion, a bending portion, and a binding portion. The bending portion connects the display portion to the binding portion and makes the binding portion bend to a non-light-emitting side of the display panel. The support layer includes a first support section on a side of the display portion close to the binding portion and a second support section on a side of the binding portion close to the display portion. The support structure and the adhesive structure are located between the first support section and the second support section, and the support layer covers the adhesive structure. Along a second direction, the adhesive structure is located on a side of the support structure close to the bending portion.

### CROSS-REFERENCE TO RELATED APPLICATION

This application claims the priority of Chinese Patent Application No.: 202411808318.2, filed on Dec. 9, 2024, the content of which is incorporated herein by reference in its entirety.

### TECHNICAL FIELD

The present disclosure generally relates to the field of display technology and, more particularly, relates to a display module and a display device.

### BACKGROUND

With the continuous development of display technology, display panels have been widely used in people's production and daily life. To better meet people's needs, the display panels can be adjusted. For example, film layers in a display panel can be adjusted to improve the overall effect of the display panel.

### SUMMARY

One aspect of the present disclosure provides a display module. The display module includes a display panel, a support layer, a support structure, and an adhesive structure. The display panel includes a display portion, a bending portion, and a binding portion, where the bending portion connects the display portion to the binding portion and the binding portion is bent to a non-light-emitting side of the display panel through the bending portion. The support layer includes a first support section and a second support section, where the first support section is located on a side of the display portion close to the binding portion and the second support section is located on a side of the binding portion close to the display portion along a first direction with the first direction being a thickness direction of the display panel. Along the first direction, the support structure and the adhesive structure are both located between the first support section and the second support section, and the support layer covers the adhesive structure. Along a second direction, the adhesive structure is located on a side of at least part of the support structure close to the bending portion, where the second direction intersects with the first direction.

Another aspect of the present disclosure provides a display device including a display module. The display module includes a display panel, a support layer, a support structure, and an adhesive structure. The display panel includes a display portion, a bending portion, and a binding portion, where the bending portion connects the display portion to the binding portion and the binding portion is bent to a non-light-emitting side of the display panel through the bending portion. The support layer includes a first support section and a second support section, where the first support section is located on a side of the display portion close to the binding portion and the second support section is located on a side of the binding portion close to the display portion along a first direction with the first direction being a thickness direction of the display panel. Along the first direction, the support structure and the adhesive structure are both located between the first support section and the second support section, and the support layer covers the adhesive structure. Along a second direction, the adhesive structure is located on a side of at least part of the support structure close to the bending portion, where the second direction intersects with the first direction.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary display module consistent with various disclosed embodiments in the present disclosure.

FIG. 2 illustrates a cross-sectional view of an exemplary display module consistent with various disclosed embodiments in the present disclosure.

FIG. 3 illustrates a cross-sectional view of another exemplary display module consistent with various disclosed embodiments in the present disclosure.

FIG. 4 illustrates a cross-sectional view of another exemplary display module consistent with various disclosed embodiments in the present disclosure.

FIG. 5 illustrates a cross-sectional view of another exemplary display module consistent with various disclosed embodiments in the present disclosure.

FIG. 6 illustrates a cross-sectional view of another exemplary display module consistent with various disclosed embodiments in the present disclosure.

FIG. 7 illustrates a cross-sectional view of another exemplary display module consistent with various disclosed embodiments in the present disclosure.

FIG. 8 illustrates a cross-sectional view of another exemplary display module consistent with various disclosed embodiments in the present disclosure.

FIG. 9 illustrates a schematic top view of a conductive layer consistent with various disclosed embodiments in the present disclosure.

FIG. 10 illustrates an exemplary adhesive structure consistent with various disclosed embodiments in the present disclosure.

FIG. 11 illustrates another exemplary adhesive structure consistent with various disclosed embodiments in the present disclosure.

FIG. 12 illustrates an exemplary support structure consistent with various disclosed embodiments in the present disclosure.

FIG. 13 illustrates another exemplary adhesive structure consistent with various disclosed embodiments in the present disclosure.

FIG. 14 illustrates an exemplary structure of a part of a display module consistent with various disclosed embodiments in the present disclosure.

FIG. 15 illustrates another exemplary structure of a part of a display module consistent with various disclosed embodiments in the present disclosure.

FIG. 16 illustrates another exemplary structure of a part of a display module consistent with various disclosed embodiments in the present disclosure.

FIG. 17 illustrates an enlarged view of an E region in FIG. 1, consistent with various disclosed embodiments in the present disclosure.

FIG. 18 illustrates a cross-sectional view of another exemplary display module consistent with various disclosed embodiments in the present disclosure.

FIG. 19 illustrates a cross-sectional view of another exemplary display module consistent with various disclosed embodiments in the present disclosure.

FIG. 20 illustrates a cross-sectional view of another exemplary display module consistent with various disclosed embodiments in the present disclosure.

FIG. 21 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted. Further, in the present disclosure, the disclosed embodiments and the features of the disclosed embodiments may be combined under conditions without conflicts. It is apparent that the embodiments described are some but not all of the embodiments of the present disclosure. Based on the disclosed embodiments, those ordinarily skilled in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and are not intended to limit the scope of the disclosure. Furthermore, a three-dimensional (3D) size including length, width, and depth should be considered during practical fabrication.

In the present disclosure, terms such as “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc., indicate orientations or positional relationships based on the orientations or positional relationships shown in the accompanying drawings, and are only for the convenience of describing the present disclosure and simplifying the description, and do not indicate or imply that the device or element referred to must have a specific orientation, be constructed and operated in a specific orientation, and therefore should not be understood as limiting the present disclosure.

In the present disclosure, relational terms such as first and second are only used to distinguish one entity or operation from another entity or operation, and do not necessarily require or imply any actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In the present disclosure, unless otherwise clearly specified and limited, the terms “installed”, “connected”, “fixed” and the like appear, should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For those skilled in the art, the specific meanings of the above terms in the present disclosure can be understood according to the specific circumstances.

In the present disclosure, when an element is referred to as being “fixed to” or “disposed on” another element, it may be directly on the other element or there may be an intermediate element. When an element is considered to be “connected to” another element, it may be directly connected to the other element or there may be an intermediate element at the same time. If present, the terms “vertical”, “horizontal”, “upper”, “lower”, “left”, “right” and similar expressions are for illustrative purposes only and are not intended to be the only embodiment.

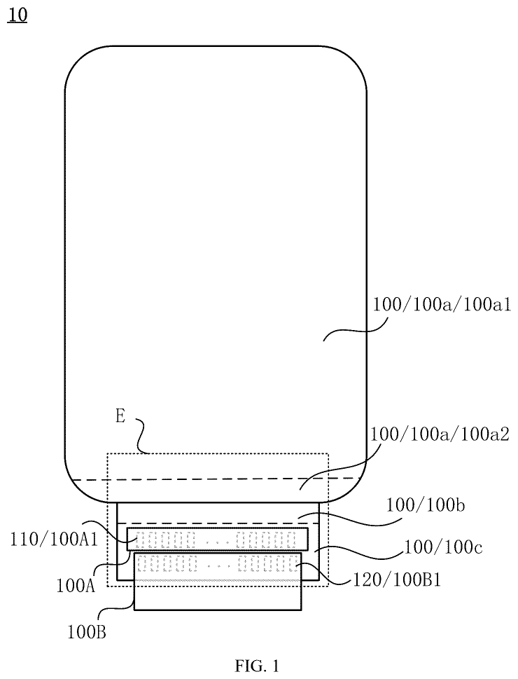

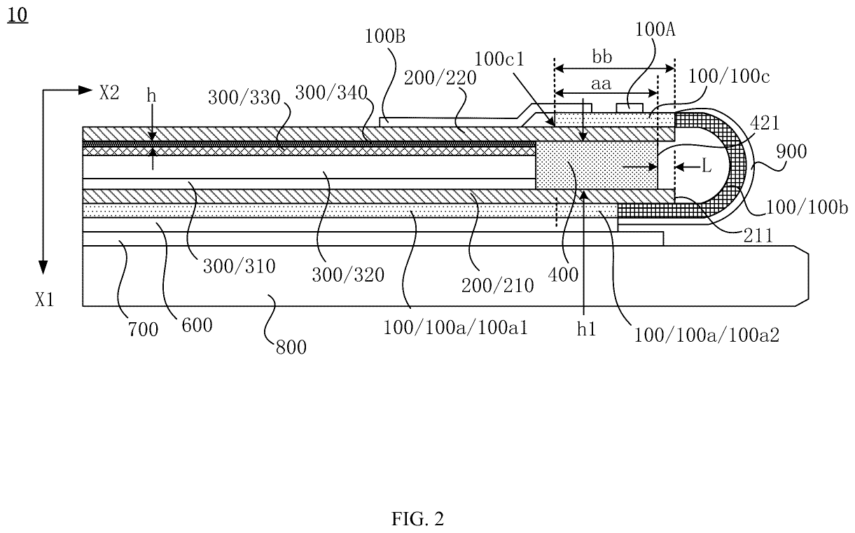

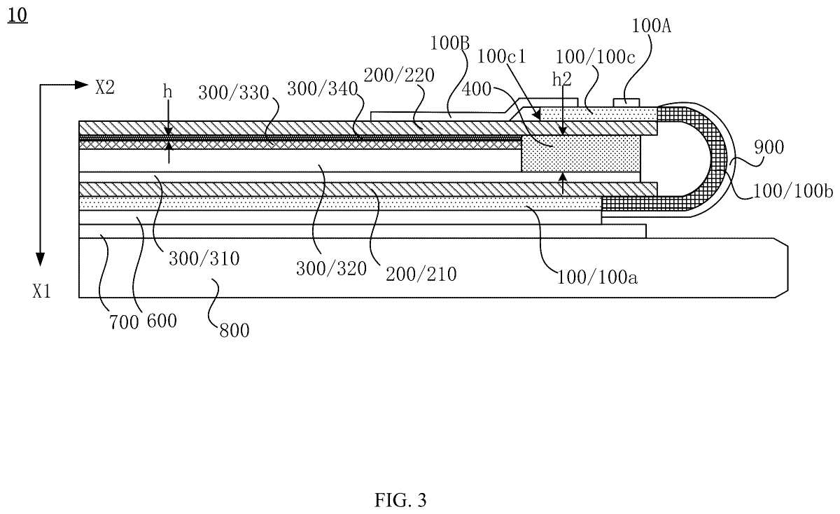

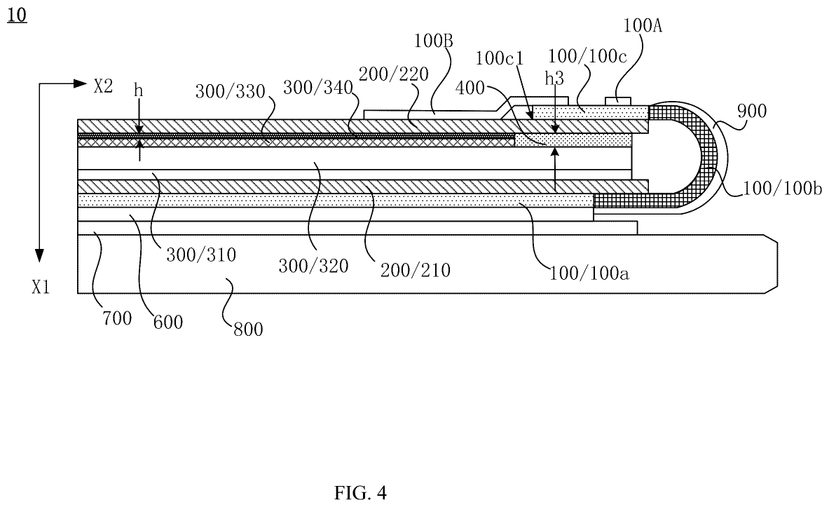

The present disclosure provides a display module. FIG. 1 is a schematic diagram of an exemplary display module provided by an embodiment of the present disclosure, FIG. 2 is a schematic diagram of a cross-sectional view of an exemplary display module, FIG. 3 is a cross-sectional view of another exemplary display module provided by an embodiment of the present disclosure, and FIG. 4 is a cross-sectional view of another exemplary display module provided by an embodiment of the present disclosure. As shown in FIG. 1 to FIG. 4, in one embodiment, the display module 10 may include a display panel 100. The display panel 100 may include a display portion 100a, a bending portion 100b, and a binding portion 100c. The bending portion 100b may connect the display portion 100a and the binding portion 100c. The binding portion 100c may be bent to a non-light-emitting side of the display panel 100 through the bending portion 100b. The display module 10 may also include a support layer 200, and the support layer 200 may include a first support section 210 and a second support section 220. Along a first direction X1, the first support section 210 may be located on a side of the display portion 100a close to the binding portion 100c, and the second support section 220 may be located on the binding portion 100c. The first direction X1 may be a thickness direction of the display panel 100. The display module 10 may also include a support structure 300 and an adhesive structure 400. Along the first direction X1, the support structure 300 and the adhesive structure 400 may both be located between the first support section 210 and the second support section 220, and the support layer 200 may cover the adhesive structure 400. Along a second direction X2, the adhesive structure 400 may be located on a side of at least a part of the support structure 300 close to the bending portion 100b. The second direction X2 may intersect with the first direction X1.

As shown in FIG. 1 to FIG. 4, the display module 10 may include the display panel 100, and the display panel 100 may include the display portion 100a. The display portion 100a may be located in a display light-emitting part of the display panel 100, and the light-emitting element (not specifically shown in the figure) arranged in the display portion 100a may be driven to perform light-emitting display, thereby realizing the display function of the display module 10 as a whole. The display panel 100 may further include the bending portion 100b and the binding portion 100c. The bending portion 100b may be bent, and the bending portion 100b may drive the binding portion 100c to be placed on the non-light-emitting side of the display panel 100 by bending. The embodiment shown in FIG. 1 with the relative positional relationship between the display portion 100a, the bending portion 100b, and the binding portion 100c, is used as an example to illustrate the present disclosure only, and the film layer structure is unfolded to show that the bending portion 100b is not bent. FIGS. 2 to 4 are side cross-sectional views of a partial structure of the display module 10, which show that the bending portion 100b is bent. For example, as shown in FIGS. 2 to 4, the bending portion 100b may be a bent arc structure, the binding portion 100c may be connected to the display portion 100a through the bending portion 100b, and the binding portion 100c may be bent toward the non-light-emitting side of the display panel 100 through the bending portion 100b, such that a lower frame area in the display module 10 may be reduced and the display screen ratio may be increased. As shown in FIG. 1, on the non-light-emitting side of the display panel 100, a plurality of binding terminals (such as the binding terminals 110 and the binding terminals 120 shown in FIG. 1) provided by the binding portion 100c may be respectively electrically connected to pads 100A1 of a driver chip 100A and to pads 100B1 of a flexible circuit board 100B. The signals provided by the driver chip 100A and the signals provided by the flexible circuit board 100B may be transmitted to the display panel 100 through the plurality of binding terminals, thereby realizing the display function of the display panel 100.

As shown in FIGS. 2 to 4, the display module 10 may further include the support layer 200, and the support layer 200 may include the first support section 210 and the second support section 220. Along the first direction X1, the first support section 210 may be located on the side of the display portion 100a close to the binding portion 100c, and the second support section 220 may be located on the side of the binding portion 100c close to the display portion 100a. It may be understood that the first support section 210 may be used to support the display portion 100a, and the second support section 220 may be used to support the binding portion 100c. Also, the display module 10 may further include the support structure 300. Along the first direction X1, the support structure 300 may be located between the first support section 210 and the second support section 220. That is, the support structure 300 may be located inside the area defined by the first support section 210 and the second support section 220. The first support section 210 and the second support section 220 may be understood as the back plate of the display module 10, and the support layer 200 and the support structure 300 may both play the support role to ensure the stability of the overall structure of the display module 10.

Further, the display module 10 may also include the adhesive structure 400, and along the first direction X1, the adhesive structure 400 may be located between the first support section 210 and the second support section 220, that is, the adhesive structure 400 and the support structure 300 may be both located inside the area defined by the first support section 210 and the second support section 220. Further, as shown in FIG. 2 to FIG. 4, along the second direction X2, the adhesive structure 400 may be located on the side of at least part of the support structure 300 close to the bending portion 100b. The bending portion 100b may drive the binding portion 100c to bend toward the non-light-emitting side of the display panel 100, such that the bending portion 100b and the binding portion 100c will have stress deflected to the non-light-emitting side, and the binding portion 100c may be located on the side of the second support portion 220 away from the display portion 100a. Therefore, the stress generated by the binding portion 100c and the bending portion 100b may cause the second support section 220 to tend to move away from the support structure 300, that is, may cause the support layer 200 to have a hidden danger of peeling, affecting the overall structural stability of the display module 10. The adhesive structure 400 arranged in the first support section 210 and the second support section 220 may have a certain viscosity, which may have a strong adhesive and fixation effect on the second support section 220, ensure the structural stability of the support layer 200, and avoid the peeling of the support layer 200. Also, the adhesive structure 400 may provide a corresponding support force, thereby ensuring the overall structural stability of the display module 10.

As shown in FIGS. 2 to 4, along the first direction X1, the support layer 200 may cover the adhesive structure 400. For example, the projection of the support layer 200 in the first direction X1 may cover the projection of the adhesive structure 400 in the first direction X1; or, the adhesive structure 400 disposed in the first support section 210 and the second support section 220 may not exceed the defined area of the first support section 210 and the second support section 220; or, the end of the first support section 210 close to the bending section 100b may be closer to the bending portion 100b than the end of the adhesive structure 400 close to the bending section 100b. In existing technologies, a support structure is generally disposed in the region corresponding to the adhesive structure 400 provided in the embodiment of the present disclosure. The support structure may generally include a film layer such as foam or copper foil that may be mostly used for support. The thickness of the adhesive layer adhered to the second support section may be relatively small, resulting in insufficient adhesive to the second support section and a higher risk of warping or peeling of the second support section. The embodiment of the present disclosure may be understood as shortening the length of at least part of the support structure 300 in the second direction X2 and setting the adhesive structure 400 in the area left after shortening, such that the adhesive structure 400 may have a larger thickness and stronger viscosity, ensuring that the support layer 200 will not be peeled off due to the existing stress to achieve the reliability of the structure of the display module 10.

As shown in FIGS. 2 to 4, along the second direction X2, the adhesive structure 400 may be located on the side of at least part of the support structure 300 close to the bending portion 100b. The support structure 300 may include multiple film layer structures, such as grid glue, foam or copper foil, etc., and the adhesive structure 400 may be located on the side of part of the film layers of the support structure 300 close to the bending portion 100b. It may also be understood as that, as shown in FIGS. 2 to 4, along the first direction X1, the thickness of the adhesive structure 400 may be set differently. The specific thickness value of the adhesive structure 400, or the film layers of the support structure 300 on which the adhesive structure 400 may be located close to the bending portion 100 b, may be differentiated according to the requirements of the display module 10, reflecting the diverse settings of the adhesive structure 400.

The adhesive structure 400 provided in the embodiment of the present disclosure may be located within the limited range of the first support section 210 and the second support section 220. Or, taking the structure shown in FIGS. 2 to 4 as an example, the adhesive structure 400 may be located below the second support section 220. Different from the protective glue filled in the bending radius limited area of the bending portion 100b, the adhesive structure 400 provided in the embodiment of the present disclosure may be mainly used to provide a larger adhesive force to the second support section 220 to ensure that it remains stable and does not warp under the action of the larger adhesive force.

Optionally, in some embodiments, the display module 10 may also include a film layer structure such as a polarizer 600, an optical glue 700, a cover plate 800, and a protective layer 900. The polarizer 600, the optical glue 700, and the cover plate 800 may be located on the side of the display portion 100a away from the binding portion 100c, and the protective layer 900 may at least cover the bending portion 100b. The polarizer 600 may be used to reduce the light incident on the display module 10 and to emit it again from the display module 10, which may reduce the interference of the external ambient light on the light emitted by the display module 10 itself, thereby ensuring the overall display effect of the display module 10. The optical glue 700 may be used to bond the overall structure to ensure the overall structural stability of the display module 10. The cover plate 800 and the protective layer 900 may be used to protect the structure of the display module 10, thereby ensuring the reliability of the display module 10. In some other different embodiments, other film layers may also be adaptively added, which will not be described one by one in the embodiments of the present disclosure.

In the display module provided by the embodiments of the present disclosure, the support structure and the adhesive structure may be disposed between the first support section and the second support section. The support layer and the support structure may be used to provide support force to the overall structure of the display module, and the adhesive structure may ensure the stability of the structure of the first support section and the second support section, to avoid peeling of the support layer and better ensure the overall structural stability of the display module.

As shown in FIGS. 2 to 4, the support structure 300 may include a first adhesive layer 310, a buffer layer 320, and a conductive layer 330 stacked along the first direction X1. The first adhesive layer 310 may be located on a side of the buffer layer 320 close to the first support subsection 210. Along the second direction X2, the adhesive structure 400 may be at least located on a side of the conductive layer 330 close to the bending portion 100b.

Further, as shown in FIGS. 2 to 4, the support structure 300 may include the first adhesive layer 310, the buffer layer 320, and the conductive layer 330. The first adhesive layer 310 may be located on the side of the first support section 210 away from the display portion 100a. The first adhesive layer 310 may be understood as a grid glue, which may be used to adhere the first support section 210 to the buffer layer 320 in the support structure 300. The buffer layer 320 may be located on the side of the first adhesive layer 310 away from the first support section 210. The buffer layer 320 may be understood as foam or other flexible structures. The buffer layer 320 may buffer the impact force or stress on the display module 10. The conductive layer 330 may be located on the side of the buffer layer 320 away from the first adhesive layer 310. The conductive layer 330 may be a copper foil or other structure with good heat conduction or electrostatic conduction effect. On the one hand, the conductive layer 330 may have a certain hardness to ensure the structural stability of the support structure 300. On the other hand, the conductive layer 330 may have thermal conductivity and electrical conductivity, which may transmit heat and conduct static electricity, thereby avoiding the influence of heat and static electricity on the display module 10, thereby ensuring the structural stability and reliability of the display module 10.

Combined with the different settings of the support structure 300, the specific setting methods of the adhesive structure 400 may be diverse, as described below.

Optionally, in one embodiment, as shown in FIG. 2, along the second direction X2, the adhesive structure 400 may be located on the side of the support structure 300 close to the bending portion 100b.

The setting position of the adhesive structure 400 in the display module 10 may be shown in FIG. 2. Along the second direction X2, the adhesive structure 400 may be located on the side of the entire support structure 300 close to the bending portion 100b. For example, along the second direction X2, the adhesive structure 400 may include a partial area located on the side of the first adhesive layer 310 close to the bending portion 100b, a partial area located on the side of the buffer layer 320 close to the bending portion 100b, and a partial area located on the side of the conductive layer 330 close to the bending portion 100b.

As shown in FIG. 2, the adhesive structure 400 may be arranged and affixed with the second support section 220, and the adhesive structure 400 may also be arranged and affixed with the first support section 210, such that the thickness of the adhesive structure 400 may be set to the maximum. The viscosity of the adhesive structure 400 may be enhanced according to the set thickness enhancement, thereby ensuring that the structural stability between the first support section 210 and the second support section 220 may be stronger, and thereby ensuring the overall structural stability of the display module 10.

Optionally, as shown in FIG. 3, along the first direction X1, the adhesive structure 400 may at least partially overlap with the first adhesive layer 310.

The setting position of the adhesive structure 400 in the display module 10 may be as shown in FIG. 3. Along the second direction X2, the adhesive structure 400 may be located on the side of the buffer layer 320 and the conductive layer 330 close to the bending portion 100b. Also, the adhesive structure 400 may be located on the side of the first adhesive layer 310 close to the second support section 220. For example, along the second direction X2, the adhesive structure 400 may include a partial area located on the side of the buffer layer 320 close to the bending portion 100b, and the adhesive structure 400 also may include a partial area located on the side of the conductive layer 330 close to the bending portion 100b.

As shown in FIG. 3, along the second direction X2, the extension length of the first adhesive layer 310 may be larger than the extension length of the buffer layer 320, and the extension length of the first adhesive layer 310 may also be larger than the extension length of the conductive layer 330. The adhesive structure 400 may be arranged in the area where the first adhesive layer 310 extends compared to the buffer layer 320. For example, one side of the adhesive structure 400 may be arranged in contact with the second support section 220, and the other side of the adhesive structure 400 may also be arranged in contact with part of the first adhesive layer 310. The adhesive structure 400 may also have a large thickness and good adhesive strength at this time, which may prevent the second support section 220 from warping and peeling. Also, there may be the first adhesive layer 310 between the adhesive structure 400 and the first support section 210, and the first adhesive layer 310 may also have a certain viscosity. The structural stability of the first support section 210 and the second support section 220 may be ensured by the first adhesive layer 310 and the adhesive structure 400.

As shown in FIG. 3, for the setting area of the adhesive structure 400, considering that the first adhesive layer 310 in the support structure 300 also has a certain viscosity, the adhesive structure 400 may be set on the side of the first adhesive layer 310 close to the second support section 220. On the one hand, the thickness of the adhesive structure 400 may be reduced, thereby reducing the process preparation cost of the adhesive structure 400. Also, the stability of the structure between the first support section 210 and the second support section 220 may be ensured, thereby ensuring the overall structural stability of the display module 10.

Optionally, as shown in FIG. 4, along the first direction X1, the adhesive structure 400 may overlap at least partially with the first adhesive layer 310 and the buffer layer 320.

Further, the setting position of the adhesive structure 400 in the display module 10 may be as shown in FIG. 4. Along the second direction X2, the adhesive structure 400 may be located on the side of the conductive layer 330 close to the bending portion 100b. Also, the adhesive structure 400 may be located on the side of the buffer layer 320 close to the second support section 220. Along the second direction X2, the adhesive structure 400 may include a partial area located on the side of the conductive layer 330 close to the bending portion 100b.

As shown in FIG. 4, along the second direction X2, the extension length of the first adhesive layer 310 and the buffer layer 320 may be larger than the extension length of the conductive layer 330. The adhesive structure 400 may be set in the area where the buffer layer 320 extends compared to the conductive layer 330. For example, one side of the adhesive structure 400 may be arranged and affixed with the second support section 220, and the other side of the adhesive structure 400 may also be arranged and affixed with part of the buffer layer 320. The adhesive structure 400 may have a good adhesive strength to prevent the second support section 220 from warping and peeling. Also, the buffer layer 320 may be disposed between the adhesive structure 400 and the first support section 210, which may ensure that the external force is also buffered in the area where the adhesive structure 400 is set, thereby ensuring the reliability of the display module 10.

As shown in FIG. 4, by setting the adhesive structure 400, the second support section 220 may be effectively prevented from being peeled off. Furthermore, the buffer layer 320 may be retained on the side of the adhesive structure 400 close to the first support section 210. On the one hand, while ensuring a good adhesive effect on the second support section 220, the thickness of the adhesive structure 400 may be reduced, thereby reducing the process preparation cost of the adhesive structure 400. On the other hand, it may be ensured that the setting area of the adhesive structure 400 may also buffer the external force, thereby ensuring the reliability of the display module 10.

As shown in FIG. 2 to FIG. 4, in one embodiment, the support structure 300 may also include a second adhesive layer 340 located between the conductive layer 330 and the second support section 220 along the first direction X1. Along the second direction X2, at least part of the adhesive structure 400 may be located on the side of the conductive layer 330 and the second adhesive layer 340 close to the bending portion 100b. Along the first direction X1, the thickness of the adhesive structure 400 may be larger than the thickness of the second adhesive layer 340.

In the present embodiment, he support structure 300 may also include the second adhesive layer 340, which may be located between the conductive layer 330 and the second support sub-section 220. The second adhesive layer 340 may also have a certain viscosity. The second adhesive layer 340 may ensure a stable adhesive relationship between the conductive layer 330 and the second support sub-section 220, and prevent the second support sub-section 220 from peeling off at the conductive layer 330.

As shown in FIG. 2 to FIG. 4, along the second direction X2, at least part of the adhesive structure 400 may be located on the side of the conductive layer 330 and the second adhesive layer 340 close to the bending portion 100b. In other words, the adhesive structure 400 may include a partial area located on the side of the conductive layer 330 close to the bending portion 100b and a partial area located on the side of the second adhesive layer 340 close to the bending portion 100b, and its thickness may be larger than the thickness of the second adhesive layer 340. Compared with the second adhesive layer 340, it may have a stronger adhesive strength to the second support section 220, ensuring that the second support section 220 of this part will not be peeled off due to warping stress.

As shown in FIG. 2 to FIG. 4, along the first direction X1, the thickness of the second adhesive layer 340 may be h. As shown in FIG. 2, along the first direction X1, the thickness of the adhesive structure 400 may be h1, where h1>h. As shown in FIG. 3, the thickness of the adhesive structure 400 may be h2, where h2>h. As shown in FIG. 4, the thickness of the adhesive structure 400 may be h3, where h3>h. In general, along the first direction X1, the thickness of the second adhesive layer 340 may be less than the thickness of the adhesive structure 400.

In one embodiment, the display module 10 may be thinned by reducing the thickness of the second adhesive layer 340. For example, the setting of the adhesive structure 400 may ensure the overall structural stability of the display module 10 and prevent the second support section 220 from peeling off at the support structure 300. Therefore, the thickness of the second adhesive layer 340 may be thinned, and the display module 10 may be thinned without affecting the structural stability of the display module 10.

Optionally, when the thickness of the adhesive structure 400 along the first direction X1 is large enough, for example, as shown in FIG. 2, and the projection area of the adhesive structure 400 along the first direction X1 is large enough, the display module 10 may ensure the structural stability of the second support section 220 only by setting the adhesive structure 400. In this case, the second adhesive layer 340 may not be set, thereby further reducing the thickness of the display module 10 and better realizing the thin design of the display module 10.

As shown in FIG. 2 to FIG. 4, the viscosity coefficient of the adhesive structure 400 may be larger than the viscosity coefficient of the second adhesive layer 340.

As shown in FIG. 2 to FIG. 4, as an example, the support structure 300 may include the second adhesive layer 340, and, along the second direction X2, the distance between the adhesive structure 400 and the bending portion 100b may be smaller than the distance between the second adhesive layer 340 and the bending portion 100b. Also, the projection of the adhesive structure 400 to the first direction X1 may overlap with the projection of the binding portion 100c to the first direction X1, such that the degree of anti-peeling protection of the adhesive structure 400 to the second support subsection 220 may be larger than the degree of anti-peeling protection of the second adhesive layer 340 to the second support subsection 220. Therefore, adjusting the viscosity coefficient of the adhesive structure 400 to be larger than the viscosity coefficient of the second adhesive layer 340 may better ensure the stability of the overall structure of the display module 10.

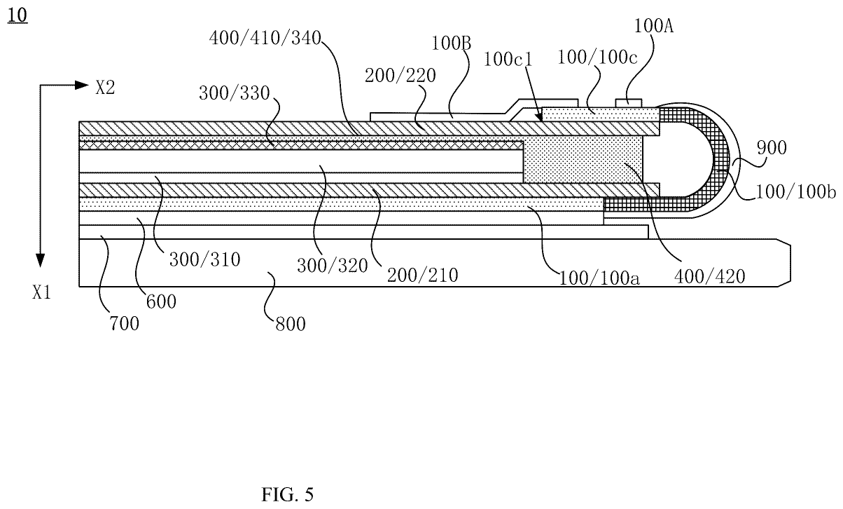

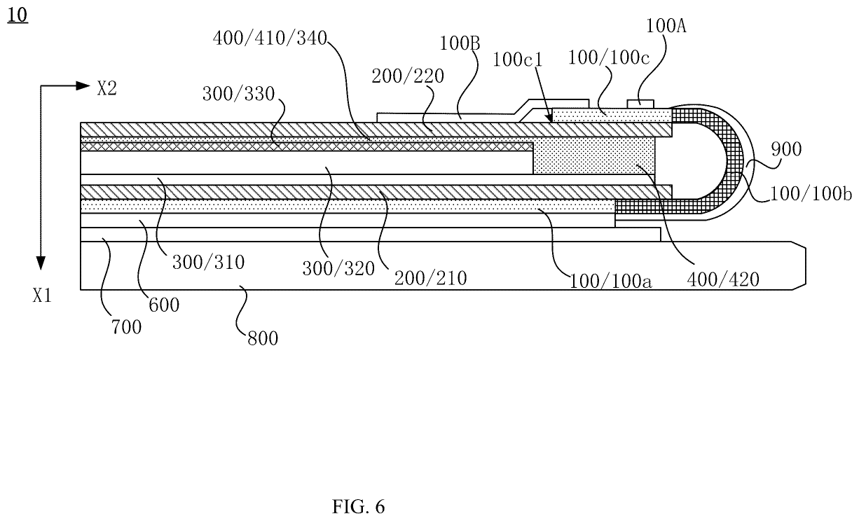

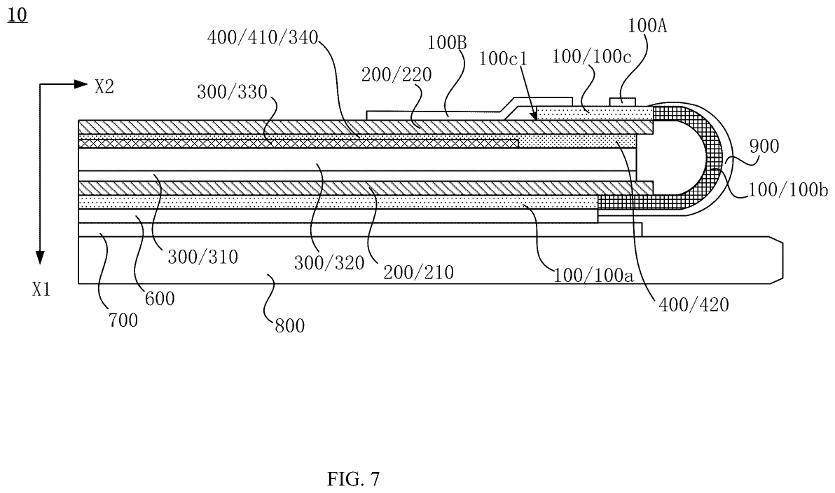

FIG. 5 is a cross-sectional schematic diagram of another display module provided by an embodiment of the present disclosure, FIG. 6 is a cross-sectional schematic diagram of another display module provided by an embodiment of the present disclosure, and FIG. 7 is a cross-sectional schematic diagram of another display module provided by an embodiment of the present disclosure. As shown in FIG. 5 to FIG. 7, in some embodiments, the adhesive structure 400 may include a first adhesive section 410 and a second adhesive section 420 connected to each other. Along the first direction X1, the first adhesive section 410 may be located between the conductive layer 330 and the second support section 220. Along the second direction X2, the second adhesive section 420 may be located on the side of the conductive layer 330 and the first adhesive section 410 close to the bending portion 100b, and the thickness of the second adhesive section 420 may be larger than that of the first adhesive section 410. The first adhesive section 410 may be multiplexed as the second adhesive layer 340.

As shown in FIGS. 5 to 7, in one embodiment, the adhesive structure 400 may include a first adhesive section 410 located between the conductive layer 330 and the second support section 220 along the first direction X1, and the first adhesive section 410 may be used to achieve adhesive between the conductive layer 330 and the second support section 220. Further, the setting position of the first adhesive section 410 may be equivalent to the second adhesive layer 340 shown in FIGS. 2 to 7, such that the first adhesive section 410 may be multiplexed as the second adhesive layer 340.

As shown in FIG. 5 to FIG. 7, the adhesive structure 400 may further include a second adhesive section 420, which may be located at least on one side of the conductive layer 330 and the first adhesive section 410 close to the bending portion 100b along the second direction X2. That is, along the second direction X2, the distance between the second adhesive section 420 and the bending portion 100b may be smaller than the distance between the first adhesive section 410 and the bending portion 100b. Also, the projection of the second adhesive section 420 in the first direction X1 may overlap with the projection of the binding portion 100c in the first direction X1, such that the anti-peeling protection degree of the second adhesive section 420 for the second support section 220 may be larger than the anti-peeling protection degree of the first adhesive section 410 for the second support section 220. Therefore, the thickness of the second adhesive section 420 may be adjusted to be larger than the thickness of the first adhesive section 410, to ensure the stability of the film layers at the second adhesive section 420 and better ensure the stability of the overall structure of the display module 10.

Further, the first adhesive portion 410 may be multiplexed as the second adhesive layer 340, and the first adhesive section 410 and the second adhesive section 420 may be made of the same material and may be simultaneously manufactured and integrated, thereby reducing the manufacturing process cost of the display module 10.

As shown in FIG. 2 to FIG. 7, along the first direction X1, the adhesive structure 400 may overlap at least part of the area of the binding portion 100c.

The orthographic projection of the adhesive structure 400 in the first direction X1 and the orthographic projection of the binding portion 100c in the first direction X1 may have an overlapping area. Since the binding portion 100c may be bent by the bending portion 100b and driven to the non-light-emitting side of the display panel 100, the position of the binding portion 100c may be more likely to cause the second support section 220 to warp and then peel off, affecting the structural stability of the display module 10. The adhesive structure 400 may have a good adhesive strength, which may effectively prevent the second support section 220 from warping and peeling off. In the second support section 220, the area overlapping with the binding portion 100c along the first direction X1 may have a more obvious tendency to warp and peel. Therefore, the setting area of the adhesive structure 400 may be adjusted to overlap with a part of the binding portion 100c, thereby more effectively ensuring the structural stability of the second support section 220. For example, the adhesive structure 400 may overlap with at least a part of the binding portion 100c along the first direction X1 (for example, the aa area in FIG. 2), to ensure the overall structural stability of the display module 10.

As shown in FIG. 2 to FIG. 7, in one embodiment, the binding portion 100c may include a binding end 100c1, and along the second direction X2, the binding end 100c1 may be the end of the binding portion 100c away from the bending portion 100b. Along the first direction X1, the adhesive structure 400 may overlap with the binding end 100c1.

As shown in FIG. 2 to FIG. 7, the binding portion 100c may include the binding end 100c1, which may be located on the side of the binding portion 100c away from the bending portion 100b. The binding end 100c1 may be understood as the end position of the display panel 100 at the binding portion 100c. Further, the bending of the bending portion 100b may drive the binding portion 100c to be on the non-light-emitting side of the display panel 100. Because of the bending of the structure, stress biased toward the non-light-emitting side may occur, which may drive the second support section 220 to peel off, thereby affecting the structural stability of the display module 10. The adhesive structure 400 provided in the embodiment of the present disclosure may have strong viscosity, which may adhere the second support section 220 to prevent the second support section 220 from peeling off.

The binding end 100c1 may be at the end of the binding portion 100c. When the binding portion 100c of the display panel 100 drives the second support section 220 to peel off, it should be from the binding end 100c1 that the second support section 220 may be gradually driven to detach from the support structure 300 in sequence. The adhesive structure 400 provided in the embodiment of the present disclosure may overlap with the binding end 100c1 along the first direction X1, or the orthographic projection of the adhesive structure 400 to the first direction X1 may overlap with the orthographic projection of the binding end 100c1 to the first direction X1. The adhesive structure 400 may prevent the second support section 220 from peeling off from the support structure 300 from the source, thereby ensuring the structural stability of the second support section 220 and the overall structural stability of the display module 10.

As shown in FIG. 2, in one embodiment, the area of the binding portion 100c may be S1, and the area of the region of the binding portion 100c overlapping with the adhesive structure 400 in the first direction X1 may be S2; where S2/S1≥50%.

The area of the binding portion 100c may be S1, and the area of the region where the adhesive structure 400 overlaps with the binding portion 100c along the first direction X1 may be S2. When the overlapping area S2 is larger, the adhesive effect of the adhesive structure 400 on the second support section 220 may be better, and the second support section 220 may be ensured not to be peeled off. For example, for S1 and S2, it may be satisfied that: S2/S1≥50%. As shown in FIG. 2, the area aa may be understood as the area corresponding to the overlap between the adhesive structure 400 and the binding portion 100c along the first direction X1, and the area bb may be understood as the area corresponding to the binding portion 100c. By increasing the overlapping area between the adhesive structure 400 and the binding portion 100c, the structural stability of the second support section 220 may be further ensured, thereby improving the overall structural stability of the display module 10.

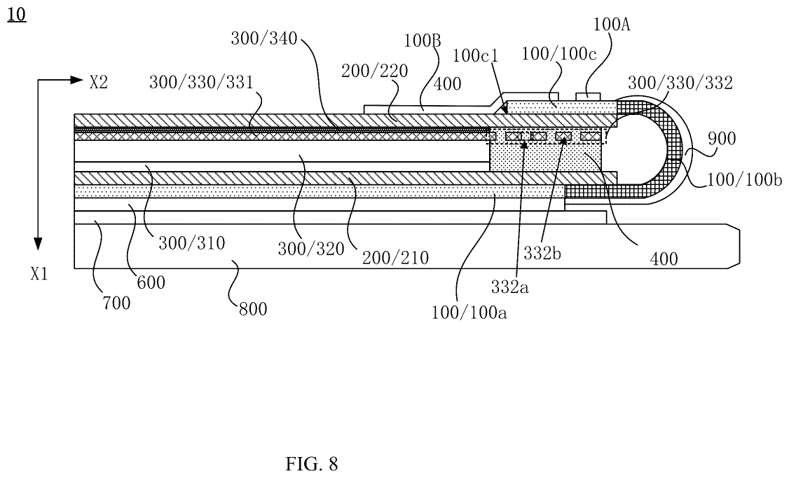

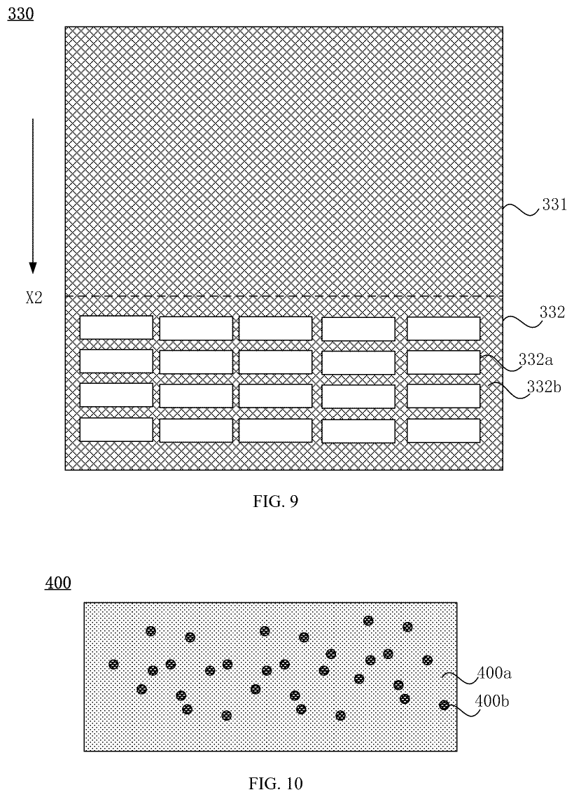

FIG. 8 is a cross-sectional schematic diagram of another exemplary display module provided by an embodiment of the present disclosure, and FIG. 9 is a top view of a conductive layer provided by an embodiment of the present disclosure. As shown in FIG. 1, FIG. 8, and FIG. 9, the conductive layer 330 may include a first conductive section 331 and a second conductive section 332. Along the second direction X2, the second conductive section 332 may be located on a side of the first conductive section 331 close to the bending portion 100b. The second conductive section 332 may include hollows 332a, and the hollow 332a may penetrate through the conductive layer 330, and the adhesive structure 400 may be bonded to the second support section 220 through the hollows 332a.

As shown in FIG. 8 and FIG. 9, the conductive layer 330 may include the first conductive section 331 and the second conductive section 332. Along the second direction X2, the second conductive section 332 may be located on the side of the first conductive section 331 close to the bending portion 100b. Further, along the first direction X1, the projection of the first conductive section 331 may not overlap with the projection of the adhesive structure 400, and the projection of the second conductive section 332 may overlap with the projection of the adhesive structure 400.

As shown in FIG. 8 and FIG. 9, the second conductive section 332 may include the hollows 332a, and the hollows 332a may penetrate through the conductive layer 330. The adhesive structure 400 may be bonded to the second support section 220 through the hollows 332a, thereby ensuring a good adhesive effect on the second support section 220 and ensuring the structural stability of the second support section 220. The conductive layer 330 may be a copper foil, which has good thermal conductivity and electrical conductivity. The conductive layer 330 may conduct heat and static electricity conducted thereto, thereby ensuring the reliability of the display module 10. Exemplarily, as shown in FIG. 8, the second conductive section 332 may overlap with the driver chip 100A disposed on the binding portion 100c, and the driver chip 100A may generate heat and static electricity when working. The setting of the second conductive section 332 may timely conduct this part of heat and static electricity, thereby ensuring the reliability of the display module 10 and improving the display effect of the display module 10.

As shown in FIG. 8 and FIG. 9, the second conductive section 332 may also include grid lines 332b that define hollows 332a, and the sum of the coverage areas of the hollows 332a may be larger than the coverage area of the grid lines 332b.

As shown in FIG. 8 and FIG. 9, the second conductive section 332 also may include the grid lines 332b, which may be arranged around the hollows 332a. The grid lines 332b may also be understood as being used to limit the hollow 332a. The grid lines 332b may dissipate the heat generated in the surrounding area, or guide the static electricity generated in the surrounding area, thereby ensuring the reliability of the display module 10. Further, the sum of the coverage areas of the hollows 332a may be larger than the coverage area of the grid lines 332b. When the coverage area of the hollows 332a is larger, the adhesive area of the adhesive structure 400 with the second support section 220 through the hollows 332a may be larger, and the structure of the second support section 220 may be more stable. For example, the large sum of the coverage areas of the hollows 332a may be that the number of the hollows 332a in the second conductive section 332 is large, or the coverage area of each hollow 332a is large.

As shown in FIG. 8 and FIG. 9, the first conductive section 331 and the second conductive section 332 may be connected.

As shown in FIG. 9, the first conduction section 331 and the second conduction section 332 may be connected to ensure the flatness and continuity of the overall structure. Exemplarily, for the preparation process of the conduction layer 330, the first conduction section 331 and the second conduction section 332 may be prepared at different positions respectively, and the first conduction section 331 and the second conduction section 332 may be electrically connected. Further, considering that the first conduction section 331 and the second conduction section 332 may be located at the same film layer position, and may be electrically connected, the first conduction section 331 and the second conduction section 332 may be an integrally formed structure, and the first conduction section 331 and the second conduction section 332 may be prepared simultaneously, thereby reducing the process preparation cost of the display module 10.

Also, by connecting the first conduction section 331 and the second conduction section 332, the heat and static electricity conducted at the second conduction section 332 may be transmitted to the first conduction section 331, ensuring the transmission effect of static electricity and heat in the display module 10. As shown in FIG. 8, the projection of the driver chip 100A along the first direction X1 may overlap with the second conduction section 332, or in other words, the distance between the driver chip 100A and the second conduction section 332 may be smaller than the distance between the driver chip 100B and the first conduction section 331. Therefore, by connecting the first conduction section 331 and the second conduction section 332, the heat and static electricity generated by the driver chip 100A conducted by the second conduction section 332 may be further transmitted, thereby ensuring the transmission effect of static electricity and heat, avoiding the influence of temperature and static electricity on the display module 10, and ensuring the overall reliability of the display module 10.

As shown in FIG. 10 which is a schematic diagram of the structure of an exemplary adhesive structure provided by an embodiment of the present disclosure, in one embodiment, the adhesive structure 400 may include an adhesive colloid 400a and thermally conductive particles 400b disposed in the adhesive colloid 400a. The thermal conductivity coefficient of the thermally conductive particle 400b may be larger than the thermal conductivity coefficient of the adhesive colloid 400a.

As shown in FIG. 10, the adhesive structure 400 may include the adhesive colloid 400a and the thermally conductive particles 400b, and the thermally conductive particles 400b may be disposed in the adhesive colloid 400a. The thermal conductivity coefficient of the thermally conductive particles 400b may be larger than the thermal conductivity coefficient of the adhesive colloid 400a, such that the adhesive structure 400 may realize the transmission of heat through the thermally conductive particles 400b and then realize the heat dissipation of the heat generated by the surrounding structure. Therefore, the adhesive structure 400 may ensure the stability of the display module 10 while also ensuring the reliability of the display module 10.

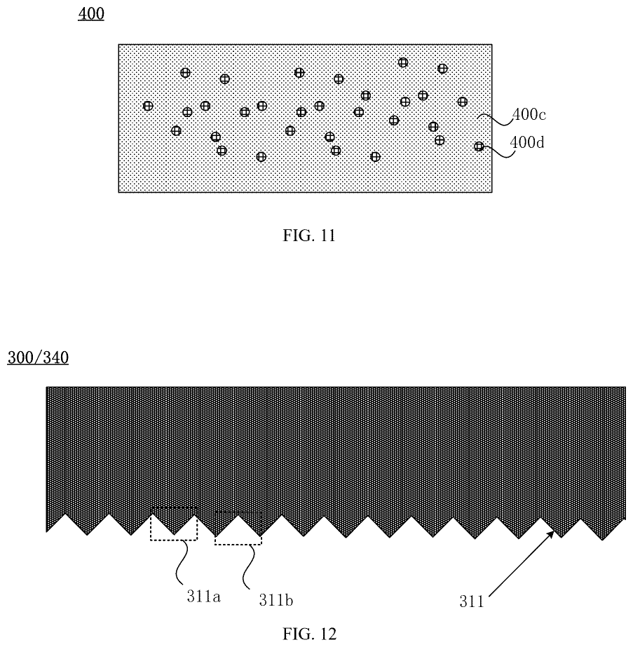

In another embodiment shown in FIG. 11 which is a schematic diagram of the structure of another exemplary adhesive structure provided by an embodiment of the present disclosure, the adhesive structure 400 may include an adhesive colloid 400c and electrically conductive particles 400d disposed in the adhesive colloid 400c. The resistivity of the electrically conductive particles 400d may be less than the resistivity of the adhesive colloid 400c.

As shown in FIG. 11, the adhesive structure 400 may include the adhesive colloid 400c and the electrically conductive particles 400d, and the electrically conductive particles 400d may be disposed in the adhesive colloid 400c. The resistivity of the electrically conductive particles 400d may be less than the resistivity of the adhesive colloid 400c, and the electrically conductive particles 400d may have good electrical conductivity, such that the adhesive structure 400 may realize the extraction of static electricity through the electrically conductive particles 400d, and then realize the extraction of static electricity from the surrounding structure. Therefore, the adhesive structure 400 may ensure the structural stability of the display module 10 while also ensuring the reliability of the display module 10.

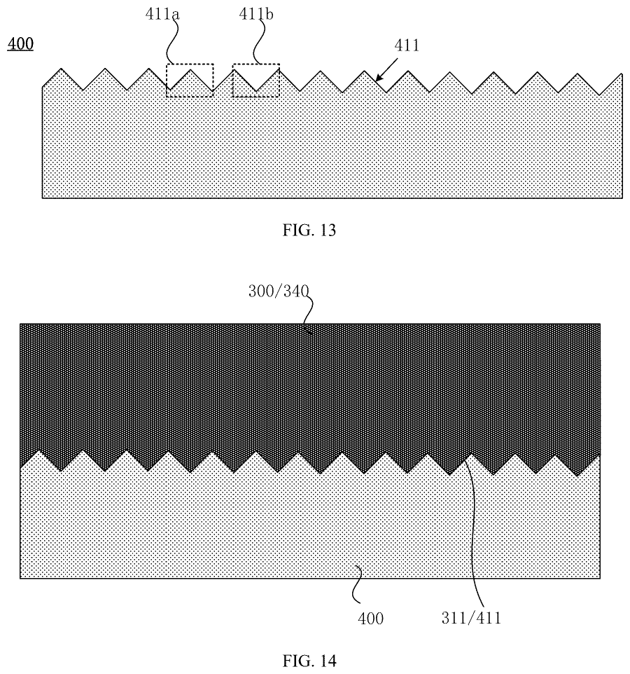

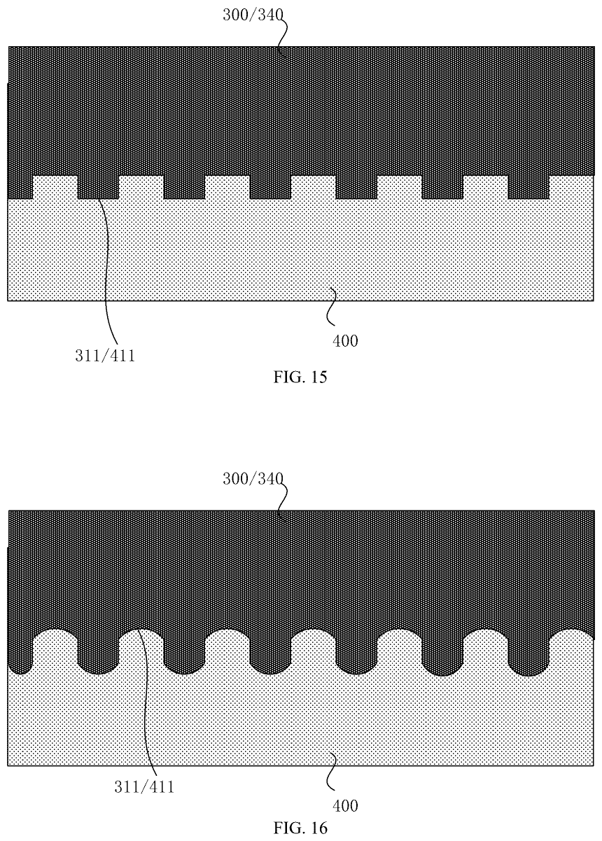

FIG. 12 is a schematic diagram of an exemplary support structure provided by an embodiment of the present disclosure, FIG. 13 is a schematic diagram of an exemplary adhesive structure provided by an embodiment of the present disclosure, FIG. 14 is a schematic diagram of a partial structure of a display module provided by an embodiment of the present disclosure, FIG. 15 is a schematic diagram of another partial structure of a display module provided by an embodiment of the present disclosure, and FIG. 16 is a schematic diagram of another partial structure of a display module provided by an embodiment of the present disclosure. In one embodiment, as shown in FIG. 2 and FIG. 12 to FIG. 16, the support structure 300 may include a support structure boundary 311 close to one side of the adhesive structure 400, and the adhesive structure 400 may include a first adhesive boundary 411 close to one side of the support structure 300. The support structure boundary 311 may include alternately arranged first protrusions 311a and first recesses 311b, and the first adhesive boundary 411 may include alternately arranged second protrusions 411a and second recesses 411b. The first protrusions 311a and the second recesses 411b may be connected, and the first recesses 311b may be connected to the second protrusions 411a.

As shown in FIG. 12, the support structure 300 may include the support structure boundary 311, and the support structure boundary 311 may be located on the boundary line of one side of the support structure 300 close to the binding portion 100b. FIG. 12 takes the second adhesive layer 340 of the support structure 300 as an example. The support structure boundary 311 may include the first protrusions 311a and the first recesses 311b, and the first protrusions 311a and the first recesses 311b may be alternately arranged. It may also be understood that there may be one first recess 311b between two adjacent first protrusions 311a, and there may be one first protrusion 311a between two adjacent first recesses 311b. The support structure boundary 311 may be an uneven boundary line.

As shown in FIG. 13, the adhesive structure 400 may include the first adhesive boundary 411, and the first adhesive boundary 411 may be located on the boundary line of one side of the adhesive structure 400 away from the binding portion 100b. The first adhesive boundary 411 may include the second protrusions 411a and a second recesses 411b, and the second protrusions 411a and the second recesses 411b may be alternately arranged, which may also be understood as there is one second recess 411b between two adjacent second protrusions 411a and one second protrusion 411a between two adjacent second recesses 411b. The first adhesive boundary 411 may be an uneven boundary line.

As shown in FIG. 14 to FIG. 16, the support structure boundary 311 and the first adhesive boundary 411 in the display module 10 may be connected. For example, as shown in FIG. 14, the first adhesive boundary 411 may include the second protrusions 411a and second recesses 411b alternately arranged. The first protrusions 311a and the second recesses 411b may be connected, and the first recesses 311b may be connected to the second protrusions 411a. By staggering the concave and convex boundary lines, the contact area between the support structure 300 and the adhesive structure 400 may be increased, thereby improving the fusion effect between the support structure 300 and the adhesive structure 400, avoiding the peeling of the film layers at the junction of the support structure 300 and the adhesive structure 400, and ensuring the stability of the overall structure of the display module 10.

As shown in FIG. 14 to FIG. 16, the morphological settings of the first protrusions 311a, the first recesses 311b, the second protrusions 411a, and the second recesses 411b may be diverse, such as triangle, rectangle, or arc, to diversify the intersection of the support structure 300 and the adhesive structure 400. The embodiments shown in FIG. 14 to FIG. 16 with three different morphologies are used as examples to illustrate the present disclosure, and they may also be adaptively adjusted according to the needs of the display module 10.

As shown in FIG. 2, along the second direction X2, the adhesive structure 400 may further include a second adhesive boundary 421 close to the side of the bending portion 100b, and the first support section 210 may include a support section boundary 211 close to the side of the bending portion 100b. The distance between the orthographic projections of the second adhesive boundary 421 on the first support section 210 and the support section boundary 211 may be L; where 0<L≤5 mm.

As shown in FIG. 2, the adhesive structure 400 may further include the second adhesive boundary 421, which may be located at a side boundary line of the adhesive structure close to the binding portion 100b. The first support section 210 may include the support section boundary 211, which may be located at a side boundary line of the first support section 210 close to the binding portion 100b. The distance between the orthographic projection of the second adhesive boundary 421 on the first support section 210 and the support section boundary 211 may be L, and L ay satisfy: 0<L≤5 mm. For example, L may be 0.8 mm, 1 mm, 3 mm or 4.5 mm, etc. It may be understood that the boundary of the adhesive structure 400 closest to the bending portion 100b may be located in the area defined by the first support section 210 and the second support section 220, such that the adhesive structure 400 may be located in the defined area of the first support section 210 and the second support section 220 as a whole. Further, the adhesive structure 400 may be arranged within the display area of the first support section 210 and the second support section 220, ensuring the overall structural stability of the display module 10 while not affecting the normal bending of the bending portion 100b, thereby ensuring the reliability of the display module 10.

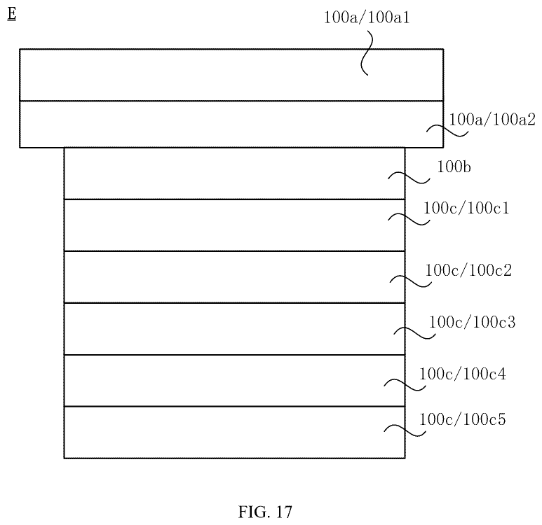

FIG. 17 is an enlarged schematic diagram of the E area in FIG. 1. As shown in FIG. 1, FIG. 2, and FIG. 17, the display portion 100a may have a display area 100a1 and a first fan-out area 100a2, and the first fan-out area 100a2 may be located on the side of the display area 100a1 close to the bending portion 100b. Along the first direction X1, the adhesive structure 400 may overlap with both the display area 100a1 and the first fan-out area 100a2.

As shown in FIG. 17, the display portion 100a may have the display area 100a1 and the first fan-out area 100a2. The first fan-out area 100a2 may be located on the side of the display area 100a1 close to the bending portion 100b. The display area 100a1 may be used to realize the display function of the display panel 10 as a whole, and the first fan-out area 100a2 may be provided with some fan-out lines (not specifically shown in the figure) transmitted to the display area 100a1. As shown in FIG. 2, the adhesive structure 400 may overlap with the display area 100a1 and the first fan-out area 100a2 along the first direction X1. By increasing the setting space of the adhesive structure 400 to the maximum extent, it may be beneficial to ensure the stability of the second support section 220 and avoid the second support section 220 from peeling off, thereby better ensuring the overall structural stability of the display module 10.

Optionally, in another embodiment, as shown in FIG. 17, the binding portion 100c may further include a second fan-out area 100c1, which may be located on one side of the binding portion 100c close to the bending portion 100b. The second fan-out area 100c2 may transmit the signal transmitted on the non-light-emitting side (such as the signal provided by the driver chip 100A or the flexible circuit board 100B), thereby ensuring the overall display function of the display module 10. Further, as shown in FIG. 17, the binding area 100c may include a test area 100c2, an electrostatic transmission area 100c3, a lighting drive test area 100c4, and a binding area 100c5 which may be sequentially away from the bending portion 100b, and the binding area 100c5 may be electrically connected to the flexible circuit board 100B. For example, the functional area of the binding portion 100c may be further enriched in design, and the embodiments of the present disclosure do not specifically limit this.

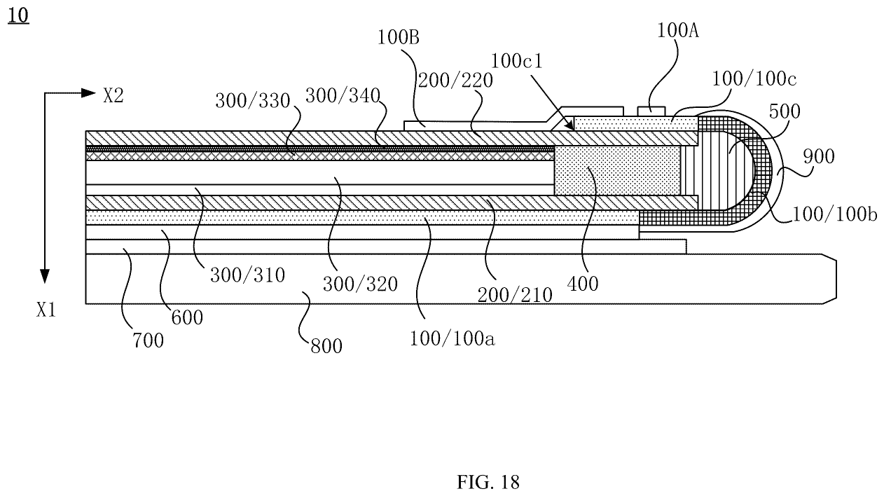

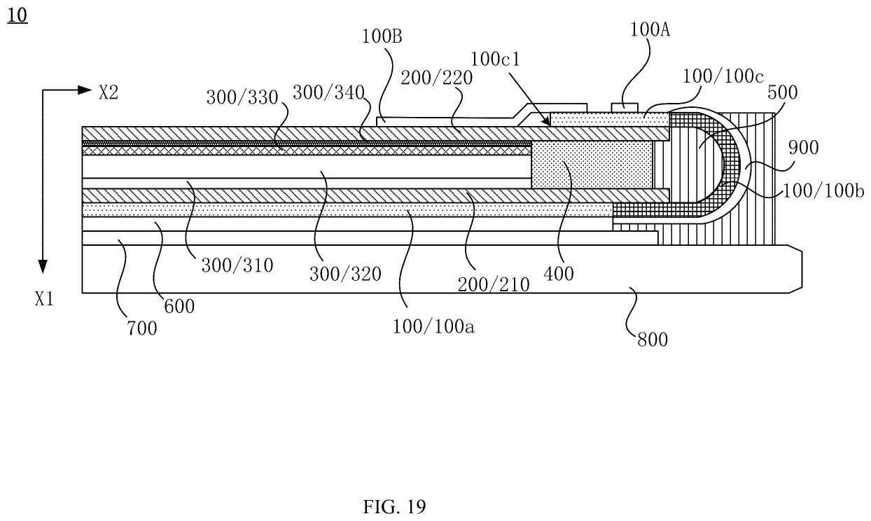

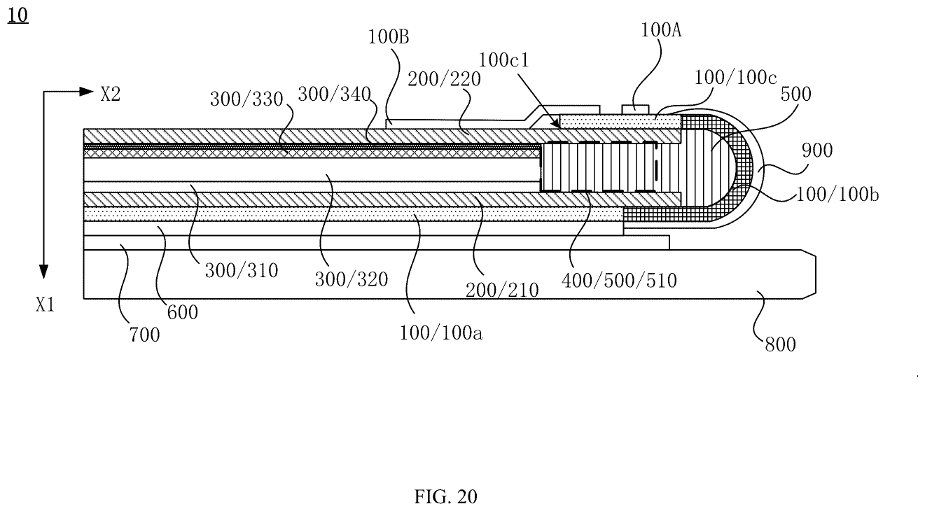

FIG. 18 is a cross-sectional schematic diagram of another exemplary display module provided by an embodiment of the present disclosure, FIG. 19 is a cross-sectional schematic diagram of another exemplary display module provided by an embodiment of the present disclosure, and FIG. 20 is a cross-sectional schematic diagram of another exemplary display module provided by an embodiment of the present disclosure. As shown in FIG. 18 to FIG. 20, in some embodiments, the display module 10 may further include an encapsulation glue structure 500, which may be located on at least one side of the bending portion 100b and in contact with the bending portion 100b.

The display module 10 may further include the encapsulation glue structure 500, which may be located on at least one side of the bending portion 100b. As shown in FIG. 18 and FIG. 20, the encapsulation glue structure 500 may be located on a side of the bending portion 100b close to the support structure 300. As shown in FIG. 19, the encapsulation glue structure 500 may have a partial structure located on a side of the bending portion 100b close to the support structure 300, and may also have a partial structure located on a side of the bending portion 100b away from the support structure 300. By setting the encapsulation glue structure 500, the space on two sides of the bending portion 100b may be filled to ensure the stability of the overall structure of the display module 10, and the overall structure may also be protected to a certain extent. Further, the encapsulation glue structure 500 may have a certain viscosity, to ensure that the bending state of the bending portion 100b may be more stable, thereby improving the overall structural stability of the display module 10.

As shown in FIG. 20, the encapsulation glue structure 500 may include a first encapsulation glue division 510, and the first encapsulation glue division 510 may be located on the side of the bending portion 100b close to the support structure 300. The first encapsulation glue division 510 may be multiplexed as at least part of the adhesive structure 400.

As shown in FIG. 20, the first encapsulation glue division 510 in the encapsulation glue structure 500 may be located on the side of the bending portion 100b close to the support structure 300, and the adhesive structure 400 may be located on the side of the support structure 300 close to the bending portion 100b. The adhesive structure 400 and the encapsulation glue structure 500 may both have a certain degree of viscosity, and the area for setting the adhesive structure 400 may be replaced by the first encapsulation glue section 510. However, it should be noted that the setting position of the adhesive structure 400 may not exceed the limited area of the first support section 210 and the second support section 220, and the first encapsulation glue division 510 may fill the entire area. Therefore, the overall occupied space of the first encapsulation glue section 510 may be larger than the occupied space of the adhesive structure 400, such that the first encapsulation glue section 510 may be multiplexed as at least part of the adhesive structure 400. By means of structural reuse, the overall process preparation cost of the display module 10 may also be reduced.

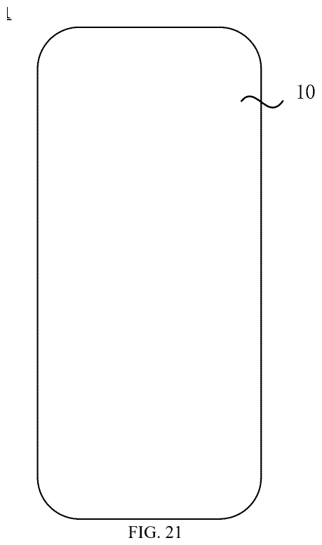

The present disclosure also provides a display device. In one embodiment shown in FIG. 21 which is a schematic diagram of the structure of a display device provided by the embodiments of the present disclosure, the display device 1 may include a display module 10 provided by any of the above embodiments. Therefore, the display device 1 provided by the embodiments of the present disclosure may have the corresponding beneficial effects of the above embodiments, which will not be repeated here. The display device 1 may be an electronic device such as a mobile phone, a computer, a smart wearable device (for example, a smart watch), or a vehicle-mounted display device.

In the present disclosure, the display panel in the display module may include the display portion, the bending portion and the binding portion. The display portion may be located on the light-emitting side of the display panel, and the bending portion may drive the binding portion to bend to the non-light-emitting side of the display panel. Further, the support layer of the display module may include the first support section and the second support section, and the display module may also include the support structure located between the first support section and the second support section. The arrangement of the first support section, the second support section and the support structure may ensure the stability of the overall structure. The display module may also include the adhesive structure located between the first support sub-section and the second support sub-section, and the adhesive structure may be located on the side of at least part of the support structure close to the bending portion. By arranging the adhesive structure, the film layers in the display module may not be peeled off because of the stress at the bending portion and the binding portion. The support layer may cover the adhesive structure, which can be understood as the adhesive structure being located at the end of a portion of the support structure close to the bending portion and the end of the support layer close to the bending portion is closer to the bending portion than the end of the adhesive structure close to the bending portion. The adhesive structure may be within the defined area of the first supporting section and the second supporting section. By arranging the adhesive structure in the display module, it may be helpful to ensure that the second support section may not be warped due to stress or the second support section may not be peeled off from the support structure, thereby better ensuring the overall structural stability of the display module.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display module, comprising a display panel, a support layer, a support structure, and an adhesive structure, wherein:
the display panel includes a display portion, a bending portion, and a binding portion, wherein the bending portion connects the display portion to the binding portion and the binding portion is bent to a non-light-emitting side of the display panel through the bending portion;
the support layer includes a first support section and a second support section, wherein the first support section is located on a side of the display portion close to the binding portion and the second support section is located on a side of the binding portion close to the display portion along a first direction with the first direction being a thickness direction of the display panel;
along the first direction, the support structure and the adhesive structure are both located between the first support section and the second support section, and the support layer covers the adhesive structure; and
along a second direction, the adhesive structure is located on a side of at least part of the support structure close to the bending portion, wherein the second direction intersects with the first direction.

2. The display module according to claim 1, wherein:
the support structure includes a first adhesive layer, a buffer layer and a conductive layer stacked along the first direction, wherein the first adhesive layer is located on a side of the buffer layer close to the first support section and the adhesive structure is at least located on a side of the conductive layer close to the bending portion along the second direction.

3. The display module according to claim 2, wherein:
along the second direction, the adhesive structure is located on a side of the support structure close to the bending portion.

4. The display module according to claim 2, wherein:
along the first direction, the adhesive structure at least partially overlaps the first adhesive layer.

5. The display module according to claim 2, wherein:
along the first direction, the adhesive structure at least partially overlaps the first adhesive layer and the buffer layer.

6. The display module according to claim 2, wherein:
the support structure further includes a second adhesive layer located between the conductive layer and the second support section along the first direction;
along the second direction, at least part of the adhesive structure is located on a side of the conductive layer and the second adhesive layer close to the bending portion;
along the first direction, a thickness of the adhesive structure is larger than a thickness of the second adhesive layer.

7. The display module according to claim 6, wherein:
a viscosity coefficient of the adhesive structure is larger than a viscosity coefficient of the second adhesive layer.

8. The display module according to claim 6, wherein:
the adhesive structure includes a first adhesive section and a second adhesive section that are connected;
along the first direction, the first adhesive section is located between the conductive layer and the second support section;
along the second direction, the second adhesive section is located on a side of the conductive layer and the first adhesive section close to the bending section;
a thickness of the second adhesive section is larger than a thickness of the first adhesive section; and
the first adhesive section is multiplexed as the second adhesive layer.

9. The display module according to claim 1, wherein:
along the first direction, the adhesive structure overlaps at least a portion of the binding portion.

10. The display module according to claim 9, wherein:
the binding portion includes a binding end, wherein the binding end is an end of the binding portion away from the bending portion along the second direction; and
along the first direction, the adhesive structure overlaps with the binding end.

11. The display module according to claim 9, wherein:
an area of the binding portion is S1 and an area of the binding portion overlapping with the adhesive structure in the first direction is S2, wherein S2/S1≥50%.

12. The display module according to claim 2, wherein:
the conductive layer includes a first conductive section and a second conductive section, wherein the second conductive section is located on a side of the first conductive section close to the bending portion along the second direction;
the second conductive section includes hollows penetrating through the conductive layer; and
the adhesive structure is bonded to the second support section through the hollows.

13. The display module according to claim 12, wherein:
the second conductive section further includes grid lines defining the hollows, wherein a sum of coverage areas of the hollows is larger than a coverage area of the grid lines.

14. The display module according to claim 12, wherein:
the first conductive section and the second conductive section are connected.

15. The display module according to claim 1, wherein:
the adhesive structure includes an adhesive colloid and thermally conductive particles disposed in the adhesive colloid, wherein a thermal conductivity coefficient of the thermally conductive particles is larger than a thermal conductivity coefficient of the adhesive colloid.

16. The display module according to claim 1, wherein:
the adhesive structure includes an adhesive colloid and electrically conductive particles disposed in the adhesive colloid, wherein resistivity of the electrically conductive particles is larger than resistivity of the adhesive colloid.

17. The display module according to claim 1, wherein:
the support structure includes a support structure boundary close to one side of the adhesive structure;
the adhesive structure includes a first adhesive boundary close to one side of the support structure;
the support structure boundary includes first protrusions and first recesses alternately arranged;
the first adhesive boundary includes second protrusions and second recesses alternately arranged; and
the first protrusions and the second recesses are connected, and the first recesses are connected to the second protrusions.

18. The display module according to claim 1, wherein:
in the second direction, the adhesive structure includes a second adhesive boundary close to the bending portion, and the first support section includes a support section boundary close to the bending portion; and
a distance between an orthographic projection of the second adhesive boundary on the first support section and the support section boundary is L, wherein 0 L≤5 mm.

19. The display module according to claim 1, wherein:
the display portion includes a display area and a first fan-out area, wherein the first fan-out area is located on a side of the display area close to the bending portion; and
along the first direction, the adhesive structure overlaps both the display area and the first fan-out area.

20. The display module according to claim 1, further comprising an encapsulation glue structure, wherein:
the encapsulation glue structure is located on at least one side of the bending portion and contacts the bending portion.

21. The display module according to claim 20, wherein:
the encapsulation glue structure includes a first encapsulation glue section, which is located on a side of the bending portion close to the support structure; and
the first encapsulation glue section is multiplexed as at least a part of the adhesive structure.

22. A display device, comprising a display module, wherein:
the display module includes a display panel, a support layer, a support structure, and an adhesive structure;
the display panel includes a display portion, a bending portion and a binding portion, wherein the bending portion connects the display portion to the binding portion and the binding portion is bent to a non-light-emitting side of the display panel through the bending portion;
the support layer includes a first support section and a second support section, wherein the first support section is located on a side of the display portion close to the binding portion and the second support section is located on a side of the binding portion close to the display portion along a first direction with the first direction being a thickness direction of the display panel;
along the first direction, the support structure and the adhesive structure are both located between the first support section and the second support section, and the support layer covers the adhesive structure; and
along a second direction, the adhesive structure is located on a side of at least part of the support structure close to the bending portion, wherein the second direction intersects with the first direction.
